(19) United States
(12) Patent Application Publication
(10) Pub. No.: US 2020/0056081 A1
(43) Pub. Date: Feb. 20, 2020

(54) Chemically Functionalized Graphene and its Applications

(71) Applicant: HK INVENT CORPORATION, Ho Chi Minh City (VN)

(72) Inventors: Nguyen Khe, Ho Chi Minh City (VN); Nguyen Phu, Ho Chi Minh City (VN)

(73) Assignee: HK INVENT CORPORATION, Ho Chi Minh City (VN)

(21) Appl. No.: 16/104,100

(22) Filed: Aug. 16, 2018

(51) Int. Cl. C09K 5/14; H05K 9/00; H05K 7/20

(52) U.S. Cl. CPC C09K 5/14; B82Y 30/00; H05K 7/2039; H05K 9/0081

(57) ABSTRACT

Certain exemplary embodiments can provide a device comprising chemically functionalized graphene. The chemically functionalized graphene comprises a graphene core molecularly doped with functional elements and a subordinate graphene shell. The graphene core has a monolayer structure. The graphene core comprises powdery graphene. The powdery graphene comprises at least one of a graphene hybrid composite, a graphene nano platelet, graphene oxide, and reduced graphene oxide, and a molecular dopant.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1A is a transmission electron microscope image of GHC having a substantially monolayer structure;

FIG. 1B is a transmission electron microscope image of a graphene nanoplatelet having a few layers in its structure;

FIG. 2A is a transmission electron microscope image of GHC having a substantially monolayer structure molecularly doped with aerogel SC;

FIG. 2B is a transmission electron microscope image of GHC having a substantially monolayer structure molecularly doped with aerogel SC;

FIG. 3 is a table showing bulk electrical resistivity (in ohm-cm) of aerogel SC doped GHC as a function of doping concentration;

FIG. 4 is a table showing bulk electrical resistivity (in ohm-cm) as a function of baking temperature in degrees Celsius;

FIG. 5 is an X-Ray Diffraction (“XRD”) chart of insulative GHC;

FIG. 6 is a table showing thermal conductivity data as an effect of diamond doping in GHC; and

FIG. 7 is a transmission electron microscope image of GHC having a substantially monolayer structure molecularly doped with diamond VOXD.

### DETAILED DESCRIPTION

Certain exemplary embodiments can provide a device comprising chemically functionalized graphene. The chemically functionalized graphene comprises a graphene core molecularly doped with functional elements and a subordinate graphene shell. The graphene core has a monolayer structure. The graphene core comprises powdery graphene. The powdery graphene comprises at least one of a graphene hybrid composite, a graphene nano platelet, graphene oxide, and reduced graphene oxide, and a molecular dopant.

Diamond is one of the best thermal conductors known. In fact, diamond is a better thermal conductor than many metals. For example, thermal conductivity, expressed in W/(m K), for exemplary substances is approximately aluminum: 237, copper: 401, diamond: 895. The carbon atoms in diamond are present as sp3spX3 hybridized and every carbon is bonded to four other carbon atoms located at vertices of a tetrahedron. Hence the bonding in diamond is a uniform, continuous three-dimensional network of C—CC—C single (sigma) bonds. Graphite on the other hand is formed from sp2spX2 hybridized carbon atoms that form a continuous two-dimensional sigma and pi bonding network. This two-dimensional network forms sheets of graphite, but there is little connection between the sheets, in fact, the sheet-sheet separation is approximately 3.4 angstroms. This might lead one to suspect that heat conduction in the two-dimensional sheet of graphite would be superior to diamond, but that heat conduction between graphite sheets would be very low. This is, in fact, an accurate description of thermal conduction in graphite. Thermal conductivity parallel to the graphite sheets is approximately 1950, but thermal conduction perpendicular to the sheet is approximately 5.7. Therefore, when thermal conduction is considered over all possible directions (anisotropic) diamond is superior to graphite.

Graphene can be considered as monolayer structure of graphite.

While single layer graphene exhibits high thermal conductivity, molecular and lattice dynamics simulations reveal that even in the presence of one or few additional layers, thermal conductivity can be significantly reduced. In fact, with increasing number of layers, thermal conductivity is expected to eventually approach the value of bulk graphite. That is the case for a graphene nano platelet (“GNP”). GNP normally has a structure comprising less than approximately 100 layers in a solid powder which can be mixed with polymer to form a GNP-polymer composite.

The thermal conductive mechanism of graphene in polymers is more complex. In general, graphene has a very high specific surface area. When being added in a polymer, large numbers of interfaces are produced. These interfaces will lead to phonon scattering and introduce ultrahigh interfacial thermal resistance. See, e.g., Thermal Conductivity of Graphene-Polymer Composites: Mechanisms, Properties, and Applications An Li, Cong Zhang and Yang-Fei Zhang * ID Department of Materials Science and Engineering, College of Engineering, Peking University, Beijing 100871, China; lian1993@pku.edu.cn (A.L.); 1601214778@pku.edu.cn (C.Z.) * Correspondence: zhangyangfei@pku.edu.cn; Tel.: +86-10-6275-9815 Received: 5 Aug. 2017; Accepted: 7 Sep. 2017; Published: 15 Sep. 2017.

Ideally, pristine graphene is monolayer structure nanocarbon, which had been known as reasonable thermal conductor as is a diamond. The thermal conductivity in graphene tends to go down when the number layers goes up. Thus, thin film graphene or pristine graphene is a better thermal conductor than graphene with a few layers as seen in powdery graphene comprising graphene oxide, reduced graphene oxide, and graphene nanoplatelets (“GNP”).

Particularly, GNP products can have a structure that comprises between approximately 4 layers and ten layers. However, thin film graphene or pristine graphene is produced in a limited quantity and it is hard to be used as a composite with polymers. In a printed circuit board (“PCB”) applications, powdery graphene is preferred as it can be blended into crosslinking polymers such as, for example, epoxy and coated on a substrate to dissipate massive heat generated from fast operating electronic devices. In heat dissipating applications for microelectronics, thermal conducting materials need to be insulating in order to avoid cross talking between devices due to electrical signal leakage. Graphene is considered as good heat dissipater. However, graphene is also a good electrical conductor and can result in cross talk. Thus it is desired to resolve this issue to achieve best performer for heat dissipating in microelectronics including PCB by developing a graphene based insulating thermal conductor.

Graphene is generally an inert material, which limits its use in multiple applications especially in the field of composite requiring strong interaction between the guess and the host materials.

U.S. Pat. No. 9,460,827, which is incorporated by reference in its entirety, disclosed graphene hybrid composite (GHC) technology in which specific solid-state carbon source (“CS”) was baked with specific metal catalyst source (“MS”) under vacuum. In that technology, specific (MS&CS) combination gave rise to GHC products showing different property values.

U.S. patent application Ser. No. 15/437,344, which is incorporated by reference in its entirety, disclosed Engrave Graphene having SSA very close to theoretical value of 2000 m²/g.

U.S. patent application Ser. No. 15/490,842, which is incorporated by reference in its entirety, disclosed Water Soluble Graphene.

U.S. patent application Ser. No. 15/859,576, which is incorporated by reference in its entirety, disclosed Reactive Graphene.

The present invention discloses a GHC based product, which is powdery but also showing monolayer structure demonstrating excellent thermal conductor that is insulative.

Certain exemplary embodiments provide a GHC based Insulating Thermal Conductor.

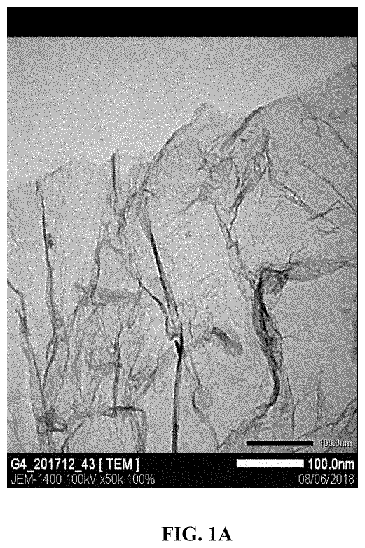

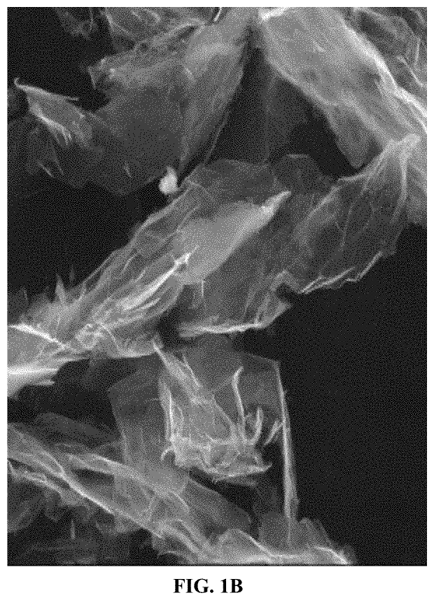

FIG. 1A is a transmission electron microscope (“TEM”) image of GHC having a substantially monolayer structure;

FIG. 1B is a transmission electron microscope image of a graphene nanoplatelet having a few layers in its structure;

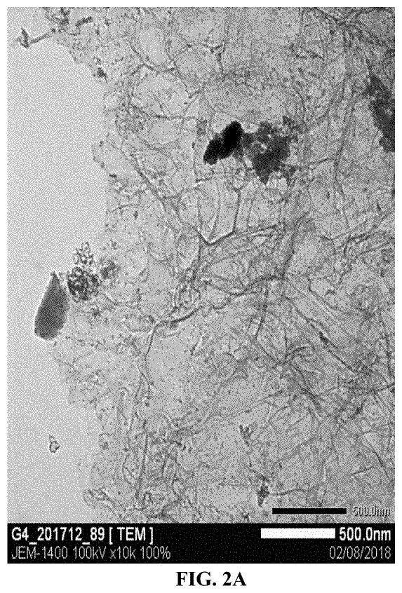

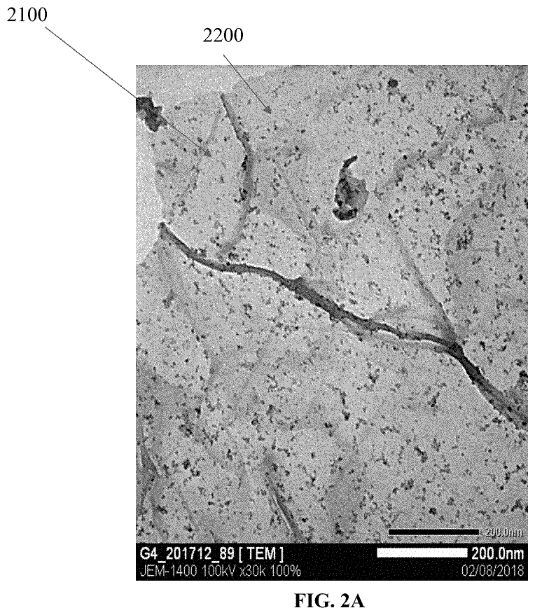

FIG. 2A is a transmission electron microscope image of GHC having a substantially monolayer structure molecularly doped with aerogel SC;

FIG. 2B is a transmission electron microscope image of GHC having a substantially monolayer structure molecularly doped with aerogel SC;

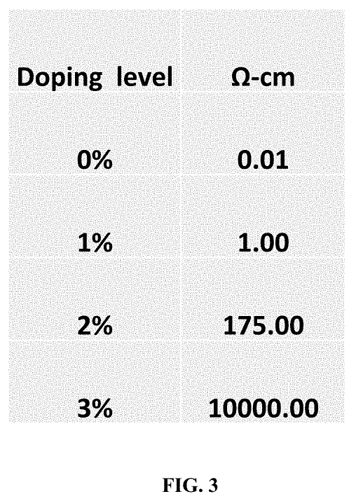

FIG. 3 is a table showing bulk electrical resistivity (in ohm-cm) of aerogel SC doped GHC as a function of doping concentration;

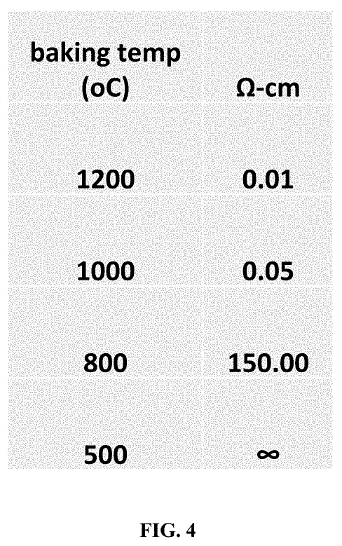

FIG. 4 is a table showing bulk electrical resistivity (in ohm-cm) as a function of baking temperature in degrees Celsius;

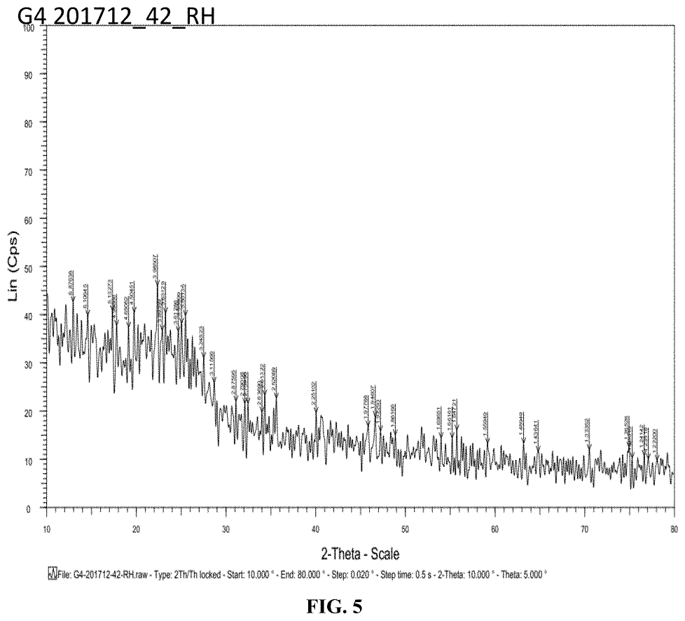

FIG. 5 is an X-Ray Diffraction (“XRD”) chart of insulative GHC.

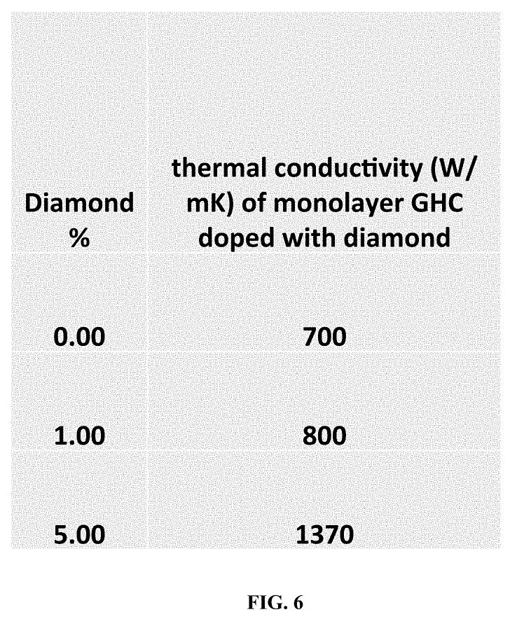

FIG. 6 is a table showing thermal conductivity data as an effect of diamond doping in GHC.

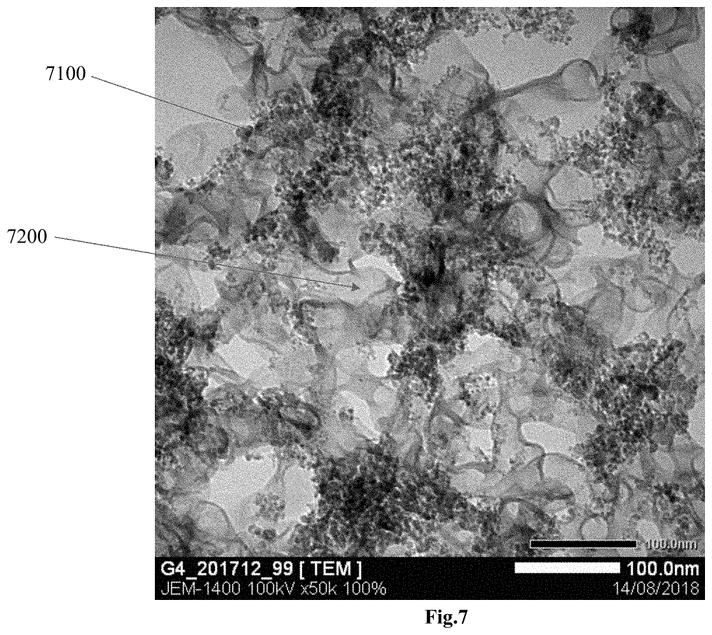

FIG. 7 is a transmission electron microscope image of GHC having a substantially monolayer structure molecularly doped with diamond powder VOXD.

Certain exemplary embodiment can provide a TEM image of monolayer powdery GHC (FIG. 1A) and that of graphene nanoplatelet (“GNP”) (FIG. 1B) having more than a few layer structure. One can see the monolayer structure shows much better transparency than the graphene nanoplatelet structure having a few layers.

Certain exemplary embodiment can provide thermal conductivity data of monolayer GHC in the range of approximately 1000 W/(m K) measured by Hot Disk 2500S (Sweden) while GNP shows a thermal conductivity of less than approximately 100 W/(m K).

Certain exemplary embodiment can provide a TEM image of GHC molecularly doped with AEROGEL SC (see, U.S. Patent Publication 20180099905) showing superior insulative properties and superior high thermal conductivity (FIG. 2A and FIG. 2B). FIG. 2A is at a scale of 500 nm and FIG. 2B is at a scale of 200 nm. One can see that FIG. 2A shows clear wide film structure and FIG. 2B magnifies spots 2100 and 2200 of AEROGEL SC, which has molecularly doped the GHC.

Generally speaking, graphene is good conductor. Some GHC prepared in conventional process (see U.S. Pat. No. 9,460,827) shows bulk electrical resistivity in the range of several mΩ-cm which is not very far from that of copper. The Aerogel SC is nanosilica comprising silanol —SiOH groups on its surface, so it is hydrophilic and highly reactive. During the thermal decomposition process of a carbon source, it can react with geminate C radicals and incorporated into the graphene network. Besides Aerogel SC, other dopants can be used such as, but not limited to, fume silica (Cab-O-syl from Cabot), halfnium oxide (HfO₂) powder. These dopants tend to reduce electrical conductivity of graphene down to several power of ten and convert highly conductive graphene into highly insulative graphene without changing the physical structure of the graphene. This process provides a product having high thermal conductivity but low electrical conductivity and the products should be named as insulating thermal conductor or thermal insulator.

Certain exemplary embodiment can provide insulating GHC by several different methods:
Lowering baking temperature during GHC forming process down to approximately 500-600 C. When baking temperature exceeds approximately 900 degree C., the products are highly electrically conductive.
Molecularly doping of GHC with insulator molecules during graphene forming process. In this case, the insulating elements are broken into nano format before being mixed up with GHC precursor. The insulator elements can be incorporated into the network of completed product. The insulator is selected from wide range of oxides such as but not limited to SiO₂, halfnium oxide HfO₂.
Certain exemplary embodiment can provide bulk resistivity data measured by powder electrical resistivity tester using four point probe technique developed by Dainam Mechanics Ltd, Vietnam. FIG. 3 is a table indicating the bulk resistivity of GHC doped with different level of Aerogel SC. It is observed that the bulk electrical resistivity of doped GHC significantly reduced with increasing doping concentration.
Certain exemplary embodiments can provide bulk resistivity data as functions of baking temperature. The result is illustrated in FIG. 4. According to this table, it is observed that the lower baking temperature gives rise to higher bulk electrical resistivity.

FIG. 5 is an XRD chart of insulative GHC. The chart indicates that insulative GHC shows amorphous structure with diffraction peak vaguely appeared at a two theta value of approximately 23°.

Certain exemplary embodiment can provide GHC showing increased thermal conductivity as the effect of diamond doping. In this case the diamond powder is supplied from Carbodeon Ltd in the format of nano powder (MOLTO) or nano dispersion (“VOXD”). The diamond powder was simply blended with precursor in a wet or dry format. The thermal conductivity of diamond doped GHC is illustrated in FIG. 6. It can be concluded that the doping of nano diamond into GHC is effective to improve the thermal conductivity.

Certain exemplary embodiments provide a system, which comprises a device. The device comprises chemically functionalized graphene. The chemically functionalized graphene comprises a graphene core molecularly doped with functional elements and a subordinate graphene shell, wherein:
the graphene core has a monolayer structure;
the graphene core comprises powdery graphene;
the powdery graphene comprises at least one of a graphene hybrid composite, a graphene nanoplatelet, graphene oxide, and reduced graphene oxide, and a molecular dopant;
the molecular dopant comprises at least one of an oxide, a hydride, a nitride, or a diamond;
the oxide comprises at least one of a nanosilica, aerogel SC, or halfnium oxide;
the chemically functionalized graphene has an amorphous structure and, when analyzed via X-ray diffraction, has pattern peaks at a 2 theta of approximately 23 degrees; and
the subordinate graphene shell is water soluble.

The device can further comprise a combination of the chemically functionalized graphene with one or more of a polymer, ceramic, metal, insulator, semiconductor, conductor, superconductor, and magnetic elements.

The device can further comprise a combination of the chemically functionalized graphene with one or more of an oxide, hydroxide.

The device can be constructed for heat dissipation.

The device can be constructed for heat dissipation in a G5 or higher telecommunications device.

The device can be constructed for heat dissipation in at least one of houses, building construction, or vehicles.

The device can be constructed for preventing electronic crosstalk.

The device can be constructed for energy generation.

The device can be constructed for energy storage.

The device can be constructed for electromagnetic wave shielding

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
2 theta—an angle of excitation as measured by a goniometer of an X-Ray Diffraction spectrophotometer in which the X-ray tube is stationary, the sample moves by the angle theta and the detector moves by the angle 2 theta.
a—at least one.
activity—an action, act, step, and/or process or portion thereof
adapter—a device used to effect operative compatibility between different parts of one or more pieces of an apparatus or system.
aerogel SC—a substantially solid material comprising silica/acid and of extremely low density, produced by removing the liquid component from a conventional gel comprising silica/acid.
amorphous structure—substantially lacking any crystalline portions.
and/or—either in conjunction with or in alternative to.
apparatus—an appliance or device for a particular purpose
associate—to join, connect together, and/or relate.
building—a structure with a roof and walls, such as a house, school, store, or factory.
can—is capable of, in at least some embodiments.
cause—to produce an effect.
Ceramic—an inorganic, non-metallic oxide, nitride or carbide material.
chemically functionalized graphene—graphene that has X-ray diffraction pattern peaks at a 2 theta of approximately 23 degrees.
circuit—an electrically conductive pathway and/or a communications connection established across two or more switching devices comprised by a network and between corresponding end systems connected to, but not comprised by the network.
comprising—including but not limited to.
configure—to make suitable or fit for a specific use or situation.
connect—to join or fasten together.
constructed to—made to and/or designed to.
convert—to transform, adapt, and/or change.
core—a central portion of chemically functionalized graphene.
coupleable—capable of being joined, connected, and/or linked together.
coupling—linking in some fashion.
create—to bring into being.
define—to establish the outline, form, or structure of
determine—to obtain, calculate, decide, deduce, and/or ascertain.
device—a machine, manufacture, and/or collection thereof.
diamond—a stone comprising substantially pure carbon, having an optically translucent crystalline form, and being the hardest naturally occurring known substance.
electronic crosstalk—a phenomenon in which a signal transmitted on one circuit or channel of a transmission system creates an undesired effect in another circuit or channel.
energy storage system—one or more components capable of acting as a repository for electrical energy.
estimate—to calculate and/or determine approximately and/or tentatively.
functional elements—a group of atoms responsible for the characteristic reactions of a particular compound.
generate—to create, produce, give rise to, and/or bring into existence.
graphene—an allotrope of carbon in the form of a two-dimensional, atomic-scale, hexagonal lattice in which one atom forms each vertex.
graphene flower—graphene synthesized in a manner that causes the graphene to have an appearance similar to a flower immediately after synthesis.
graphene hybrid composite—a substance comprising graphene as described in U.S. Pat. No. 9,460,827, which substance comprises carbon nanotubes.
graphite—a gray, crystalline, allotropic form of carbon.
heat dissipation—thermal energy transfer to a surrounding environment.
house—a building constructed to be occupied by humans and/or animals.
initialize—to prepare something for use and/or some future event.
install—to connect or set in position and prepare for use.
insulator—a material whose internal electric charges do not flow freely;
very little electric current will flow through it under the influence of an electric field.
may—is allowed and/or permitted to, in at least some embodiments.
metal—a solid material that is typically hard, shiny, malleable, fusible, and ductile, with good electrical and thermal conductivity (e.g., iron, gold, silver, copper, and aluminum, and alloys such as brass and steel).
method—a process, procedure, and/or collection of related activities for accomplishing something.
molecule—a smallest part of chemical compound.
molecular dopant—an impurity added at a molecular level.
molecularly doped—having an impurity added at a molecular level.
monolayer structure—having substantially a single layer.
nanoadditive—a substance that has a maximum dimension between 1 and 100 nanometers.
nanocarbon—carbon nanoparticles.
nanofiller—a doping agent distributed in the matrix of a composite, whose individual elements have at least one of their dimensions in the nanoscale.
nanoparticles—solids that have a maximum dimension between 1 and 100 nanometers.
nanoplatelet—a disk-shaped nanoparticle.
nanoscale—a region of dimension scale between 1 and 100 nanometers, in which all major interactions in nanosystems occur and which limits geometrical dimensions of nano-objects in one or more dimensions.
nanosilica—a nanoparticle of silica.
nanotube—a nanoparticle of carbon that comprises a substantially cylindrical portion.
particle—a tiny piece of matter.
particle size—a largest dimension of a solid minute portion of matter.
plurality—the state of being plural and/or more than one.
polymer—a substance that has a molecular structure consisting primarily or entirely of a large number of similar units bonded together.
powdery—solid particles that have a maximum dimension between 100 and 2,500 nanometers.
predetermined—established in advance.
probability—a quantitative representation of a likelihood of an occurrence.
project—to calculate, estimate, or predict.
provide—to furnish, supply, give, and/or make available.
reactive graphene—graphene comprising a graphene core and a shell that comprises one or more reactive functional groups.
receive—to get as a signal, take, acquire, and/or obtain.
recommend—to suggest, praise, commend, and/or endorse.
reduced graphene oxide—graphene oxide that is subjected to thermal, chemical or electrical treatment such that electrons are added; in reduced graphene oxide there are some defects and some oxygen functional groups in or on the reduced graphene oxide surface.
repeatedly—again and again; repetitively.
request—to express a desire for and/or ask for.
select—to make a choice or selection from alternatives.
semiconductor—a crystalline or amorphous solids with an electrical resistance that is higher than typical resistance materials, but still of much lower resistance than insulators. Their resistance decreases as their temperature increases, which is behavior opposite to that of a metal. Semiconductor conducting properties may be altered in useful ways by the deliberate, controlled introduction of impurities (“doping”) into the crystal structure, which lowers electrical resistance but also permits the creation of semiconductor junctions between differently-doped regions of the extrinsic semiconductor crystal. The behavior of charge carriers, which include electrons, ions and electron holes at these junctions, is the basis of diodes, transistors and all modern electronics.
set—a related plurality.
specific surface area—a property of solids defined as the total surface area of a material per unit of mass.
store—to place, hold, and/or retain.
subordinate graphene shell—a structure surrounding a core of chemically functionalized graphene.
substantially—to a great extent or degree.
supercapacitor—a high-capacity electrochemical capacitor with capacitance values much higher than other capacitors (but lower voltage limits) that bridge a gap between electrolytic capacitors and rechargeable batteries. Supercapacitors utilize use electrostatic double-layer capacitance or electrochemical pseudocapacitance. Supercapacitors have a range of capacitances between approximately 0.001 F and approximately 6,000 F. Supercapacitors have cell voltages ranging between approximately 1.4 volts and approximately 125 volts.
superconductor—a substance that has substantially zero electrical resistance and expulsion of magnetic flux fields when it is cooled below a characteristic critical temperature.
support—to bear the weight of, especially from below.
system—a collection of mechanisms, devices, machines, articles of manufacture, processes, data, and/or instructions, the collection designed to perform one or more specific functions.
transmit—to send as a signal, provide, furnish, and/or supply.
vehicle—a system that transports people or goods such as a car, truck, or cart.
via—by way of and/or utilizing.
weight—a value indicative of importance.
X-Ray Diffraction—a method of analyzing substances that measures a scattered intensity of an X-ray beam hitting a sample as a function of incident and scattered angle, polarization, and wavelength or energy.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing figure, etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing figure, etc.) of this application, other than the claims themselves, is to be regarded as illustrative in nature, and not as restrictive, and the scope of subject matter protected by any patent that issues based on this application is defined only by the claims of that patent.

What is claimed is:

1. A system comprising:
a device comprising chemically functionalized graphene, said chemically functionalized graphene comprising a graphene core molecularly doped with functional elements and a subordinate graphene shell, wherein:
said graphene core has a monolayer structure, said graphene core comprising powdery graphene, said powdery graphene comprising at least one of a graphene hybrid composite, a graphene nanoplatelet, graphene oxide, and reduced graphene oxide, and a molecular dopant, wherein:
said molecular dopant comprises at least one of an oxide, a hydride, a nitride, or a diamond,
said oxide comprises at least one of a nanosilica, aerogel SC, or halfnium oxide;
said chemically functionalized graphene has an amorphous structure and, when analyzed via X-ray diffraction, has pattern peaks at a 2 theta of approximately 23 degrees;
said subordinate graphene shell is water soluble.

2. The system of claim 1, wherein:
said device further comprises a combination of said chemically functionalized graphene with one or more of a polymer, ceramic, metal, insulator, semiconductor, conductor, superconductor, and magnetic elements.

3. The system of claim 1, wherein:
said device further comprises a combination of said chemically functionalized graphene with one or more of an oxide, hydroxide.

4. The system of claim 1, wherein:
said device is constructed for heat dissipation.

5. The system of claim 1, wherein:
said device is constructed for heat dissipation in a G5 or higher telecommunications device.

6. The system of claim 1, wherein:
said device is constructed for heat dissipation in at least one of houses, building construction, or vehicles.

7. The system of claim 1, wherein:
said device is constructed for preventing electronic crosstalk.

8. The system of claim 1, wherein:
said device is constructed for energy generation.

9. The system of claim 1, wherein:
said device is constructed for energy storage.

10. The system of claim 1, wherein:
said device is constructed for electromagnetic wave shielding.
